(19) United States
(12) Patent Application Publication
(10) Pub. No.: US 2004/0007762 A1
(43) Pub. Date: Jan. 15, 2004

(54) METHOD FOR FABRICATING ADAPTOR FOR ALIGNING AND ELECTRICALLY COUPLING CIRCUIT DEVICES HAVING DISSIMILAR CONNECTIVITY PATTERNS

(76) Inventor: Brock J. LaMeres, Colorado Springs, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/193,547

(22) Filed: Jul. 11, 2002

(51) Int. Cl. H01L 27/082; H01L 27/102; H01L 29/70; H01L 31/11

(52) U.S. Cl. 257/583

(57) ABSTRACT

An adapter and routing method for coupling an FPGA ball grid array to an ASIC ball grid array is disclosed. In one embodiment, the invention is a system for coupling circuit devices having dissimilar connectivity patterns, comprising a connection device having a first connectivity pattern on a first surface and a second connectivity pattern on a second surface, and a first conductor associated with the first connectivity pattern and a second conductor associated with the second connectivity pattern. The system also includes a first blind via extending from the first surface partway through the connection device, the first blind via forming the first conductor, a second blind via extending from the second surface partway through the connection device, the second blind via forming the second conductor, where the first blind via is mechanically isolated from the second blind via and the first blind via is electrically coupled to the second blind via through a common electrical connection to a through-hole via. Related methods of forming the coupling device and computer readable media are also provided.

### TECHNICAL FIELD

The present invention relates generally to electronic circuit design, and, more particularly, to an adapter for aligning and electrically coupling circuit devices having dissimilar connectivity patterns.

### BACKGROUND OF THE INVENTION

Many electrical designs incorporate at least one application specific integrated circuit (ASIC) into the design. The circuit design generally includes one or more electrical components that are interconnected using a printed circuit board (PCB). An ASIC is generally an integrated circuit that is created to perform one or more specific tasks. However, the ASIC is also typically part of a circuit design that may include other ASICS and many other circuit components. To minimize the amount or resources used in developing a circuit design, it is useful to prove, or verify, the circuit design by modeling, or emulating, the performance of the ASIC and the other components in the circuit design. This allows the design of the entire circuit, or portion of the circuit, to be verified before finalizing the design of the ASIC and fabricating the ASIC. Changes to the ASIC are difficult once the ASIC is fabricated because the ASIC is generally not readily reprogrammable.

An ASIC, or more accurately the operation of the ASIC, is typically emulated by using a component known as a field programmable gate array (FPGA). Unlike an ASIC, an FPGA is a hardware component that can be easily programmed and reprogrammed to perform different functions and to adjust the performance of the design. For example, an FPGA can be programmed to perform the tasks associated with an ASIC. In this manner, an FPGA can be used in place of an ASIC to verify the design of the circuit before the ASIC is fabricated. If testing indicates that operation is not as designed, the FPGA can be reprogrammed until proper operation of the ASIC design and the circuit is achieved. Then, the ASIC can be finalized and fabricated.

When using an FPGA to emulate an ASIC, it is desirable to place the FPGA into the same location on the circuit board that the ASIC will occupy. Unfortunately, because the location of the contacts on an FPGA are typically different than the location of the contacts on an ASIC, a connection device, such as translator PCB, is typically required to house the FPGA and to route the signals from the circuit PCB (which is designed to receive the ASIC) to the contacts on the FPGA. A typical translator PCB will have a first surface designed to receive the FPGA and a second surface designed to fit the location on the circuit PCB at which the ASIC will be placed. Disregarding for a moment any mechanical connectors and receptacles, the translator PCB includes the contact pattern of the FPGA on the first (e.g., upper) surface and the contact pattern of the ASIC on the second (e.g., lower) surface.

A common electrical and mechanical connection arrangement, referred to as a packaging style, for both ASICs and FPGAs is referred to as a ball grid array (BGA). The BGA generally uses a plated through-hole, which is typically referred to as a “via,” on the circuit PCB to provide an electrical and mechanical connection to a corresponding contact on the device package. A solder ball is placed on an exposed surface of the via and connects the device contact to the appropriate contact on the circuit PCB. Standard PCB vias traverse the entire thickness of a PCB and are typically plated through so that connection can be made to the different layers (e.g., signal, power, ground, etc.) of the PCB. Unfortunately, because the contact locations of the FPGA differ from the contact location of the ASIC, if the BGA pattern for the FPGA is placed on one surface of the translator PCB and the BGA pattern for the ASIC is placed on the opposite surface of the translator PCB directly opposite the FPGA, there would likely be incidental and unintended contact between some of the contacts on the FPGA and the ASIC through the vias.

One manner of addressing this problem is to simply enlarge the size of the translator PCB so that the BGA pattern of the FPGA does not overlap and is offset from the BGA pattern of the ASIC. Unfortunately, this increases the overall area occupied by the translator PCB. If the translator PCB becomes appreciably larger than the space on the circuit PCB reserved for the ASIC, components on the circuit PCB may have to be relocated to provide space for the translator PCB. Further, extended circuit trace routing, which may be required due to the offset between the FPGA and the ASIC, on the translator PCB may degrade the electrical quality of the signals passed between the FPGA and the circuit PCB. These drawbacks decrease the integrity and value of the emulation because the FPGA may not emulate a true representation of the circuit design.

Therefore, there is a need in the industry for an efficient way of loading an FPGA onto a printed circuit board that is designed to incorporate an ASIC.

### SUMMARY OF THE INVETION

Embodiments of the invention include an adapter and routing method for coupling an FPGA to an ASIC that reside directly opposite one another on a circuit board. In one embodiment, the invention is a system for coupling circuit devices having dissimilar connectivity patterns, comprising a connection device having a first connectivity pattern on a first surface and a second connectivity pattern on a second surface, and a first conductor associated with the first connectivity pattern and a second conductor associated with the second connectivity pattern. The system also includes a first blind via extending from the first surface partway through the connection device, the first blind via forming the first conductor, a second blind via extending from the second surface partway through the connection device, the second blind via forming the second conductor, where the first blind via is mechanically isolated from the second blind via and the first blind via is electrically coupled to the second blind via through a common electrical connection to a through-hole via.

Related methods of forming the coupling device and computer readable media are also provided. Other systems, methods, features, and advantages of the invention will be or become apparent to one with skill in the art upon examination of the following figures and detailed description. It is intended that all such additional systems, methods, features, and advantages be included within this description, be within the scope of the invention, and be protected by the accompanying claims.

### BRIEF DESCRIPTION OF THE DRAWINGS

Embodiments of the present invention, as defined in the claims, can be better understood with reference to the following drawings. The components within the drawings are not necessarily to scale relative to each other, emphasis instead being placed upon clearly illustrating the principles of the present invention.

FIG. 1 is a perspective view illustrating a circuit design 10 incorporating the translator printed circuit board (PCB) of the invention.

FIG. 2A is a schematic view illustrating the translator PCB of FIG. 1.

FIG. 2B is a schematic view also illustrating the translator PCB of FIG. 1.

FIG. 3A is a cross-sectional view illustrating the PCB layer stack of the translator PCB of FIGS. 1, 2A and 2B.

FIG. 3B is a schematic view illustrating the layer structure of the PCB structure of FIG. 3A.

FIG. 4 is a flowchart illustrating the routing methodology described-above with respect to FIG. 3A.

FIG. 5 is a block diagram illustrating a simplified computer system for implementing the circuit routing method described above with respect to FIGS. 3A and 4.

### DETAILED DESCRIPTION OF THE PREFERRED EMBODIMENT

The embodiments of the invention described below are applicable to any circuit design in which it is desirable to electrically and mechanically couple circuit devices having dissimilar ball grid array patterns, while minimizing the amount of space on a circuit design. Furthermore, while described in detail below as coupling an FPGA ball grid array to an ASIC ball grid array, the invention is applicable to other device types of circuit devices. Further still, while described below as useful for designing an adapter, the circuit routing methodology to be described below can be used to electrically couple conductors on opposite surfaces of any printed circuit board, printed wiring board, or circuit card.

The adapter for aligning and electrically coupling circuit devices having dissimilar ball grid array patterns is typically implemented as a hardware element. However, as will be described below, the method of designing and routing the connections within the adapter can be implemented as a circuit routing methodology, which can be implemented in hardware, software, firmware, or a combination thereof In the preferred embodiment(s), the invention is implemented using a combination of hardware and software or firmware that is stored in a memory and that is executed by a suitable instruction execution system. For example, when a computer aided design (CAD) system is used to design the circuit and the circuit layout, the method of the invention can be stored in a memory and executed by a processor associated with the CAD system, as will be described below.

The hardware portion of the invention can be implemented with any or a combination of the following technologies, which are all well known in the art: a discrete logic circuit(s) having logic gates for implementing logic functions upon data signals, an application-specific integrated circuit (ASIC) having appropriate combinational logic gates, a programmable gate array(s) (PGA), a field-programmable gate array (FPGA), etc. The software portion of the invention can be stored in one or more memory elements and executed by a suitable general purpose or application specific processor.

The program for routing the connections within the adapter, which comprises an ordered listing of executable instructions for implementing logical functions, can be embodied in any computer-readable medium for use by or in connection with an instruction-execution system, apparatus, or device, such as a computer-based system, processor-containing system, or other system that can fetch the instructions from the instruction execution system, apparatus, or device and execute the instructions. In the context of this document, a “computer-readable medium” can be any means that can contain, store, communicate, propagate, or transport the program for use by or in connection with the instruction execution system, apparatus, or device. The computer-readable medium can be, for example but not limited to, an electronic, magnetic, optical, electromagnetic, infrared, or semiconductor system, apparatus, device, or propagation medium. More specific examples (a nonexhaustive list) of the computer-readable medium would include the following: an electrical connection (electronic) having one or more wires, a portable computer diskette (magnetic), a random access memory (RAM) (electronic), a read-only memory (ROM) (electronic), an erasable-programmable read-only memory (EPROM or Flash memory) (electronic), an optical fiber (optical), and a portable compact disc read-only memory (CDROM) (optical). Note that the computer-readable medium could even be paper or another suitable medium upon which the program is printed, as the program can be electronically captured, via for instance optical scanning of the paper or other medium, then compiled, interpreted or otherwise processed in a suitable manner if necessary, and then stored in a computer memory.

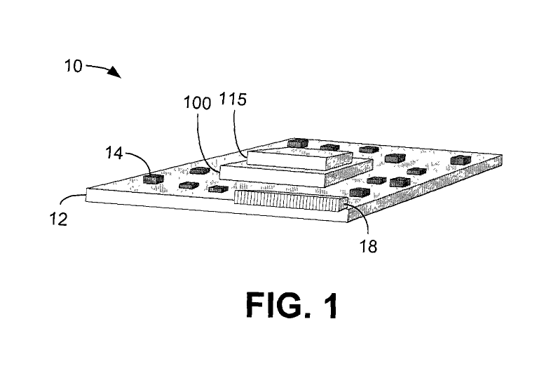

FIG. 1 is a perspective view illustrating a circuit design 10 incorporating the translator printed circuit board (PCB) of the invention. The circuit design 10 may include a number of different components, an exemplary one of which is illustrated using reference numeral 14, connected to a circuit design PCB 12. The circuit design PCB 12 can be any electronic circuit card or wiring board that incorporates and interconnects a number of components. The circuit design PCB 12 also includes a connector 18 designed to couple the circuit design PCB 12 to another system or device, external cabling, etc.

The circuit design 10 also includes a translator PCB 100. The translator PCB 100 is used in situations in which, for example, an application specification integrated circuit (ASIC) (not shown) is part of the circuit design 10, but not yet available. In many instances, the circuit design PCB 12 may be available before the ASIC is available. In such a case, it may be desirable to test the circuit design 10 using a field programmable gate array (FPGA) 115. An FPGA can be used to emulate the functionality of the ASIC and is generally used because of the ease in which it can be reprogrammed. Unfortunately, an FPGA and an ASIC rarely have the same connectivity pattern (ball grid array pattern). Accordingly, it is desirable to have an adapter to connect the FPGA 115 to the circuit design PCB 12 in the same location and approximately the same size as the ASIC.

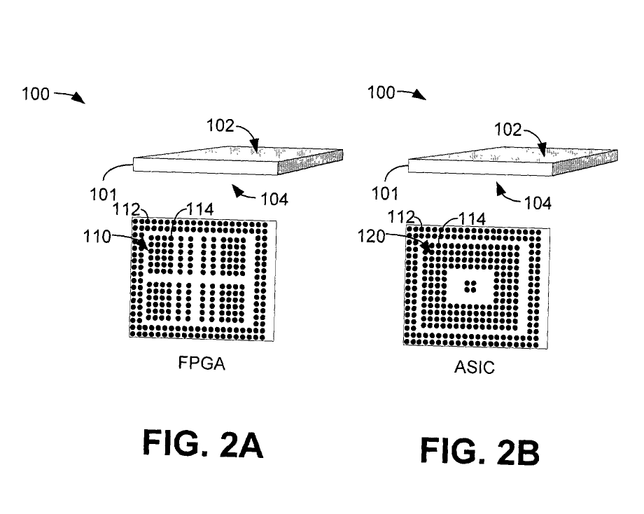

FIG. 2A is a schematic view illustrating the translator PCB 100 of FIG. 1. In FIG. 2A, the translator PCB 100 includes a PCB structure 101, which includes a first surface 102 and a second surface 104. The PCB structure can be any available material that is used to construct printed circuit boards or printed wiring boards. The PCB structure 101 is chosen depending on the electrical performance desired from the translator PCB 100. In the illustrated embodiment, the first surface 102 includes a connectivity pattern corresponding to an FPGA ball grid array (BGA) pattern 110. The FPGA ball grid array pattern 110 is the pattern that appears on the connection side of a FPGA 115 (FIG. 1). It should be noted that while illustrated using a BGA pattern, the invention is applicable to any packaging format.

FIG. 2B is a schematic view also illustrating the translator PCB 100. In FIG. 2B, the second surface 104 of the translator PCB 100 includes a connectivity pattern corresponding to an ASIC ball grid array pattern 120. The ASIC ball grid array pattern 120 is the connection pattern of the ASIC that is designed to be incorporated into the circuit design 10 (FIG. 1). As illustrated, the first surface 102 includes the FPGA ball grid array pattern 110 and the second surface 104 includes the ASIC ball grid array pattern 120. As mentioned above, while illustrated using a BGA pattern, the invention is applicable to any packaging format.

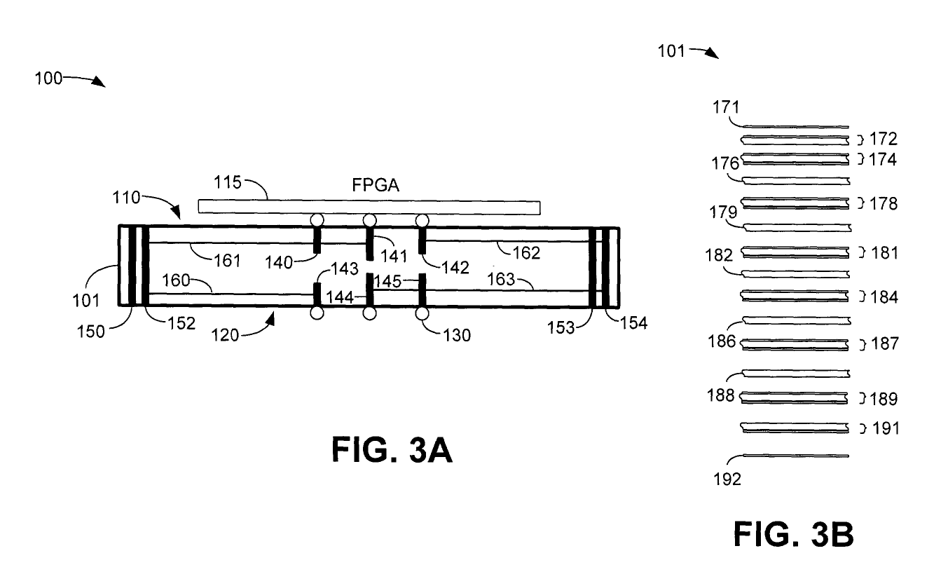

In accordance with an aspect of the invention the FPGA ball grid array pattern 110 and the ASIC ball grid array pattern 120 are formed on opposite sides of the PCB structure 101 and occupy approximately the same area. As will be described in greater detail below, the FPGA ball grid array pattern 110 and the ASIC ball grid array pattern 120 are formed and interconnected using two kinds of vias. Conventional through-hole vias, an exemplary one of which is illustrated using reference numeral 112, are formed generally around the periphery of the FPGA ball grid array pattern 110 and the ASIC ball grid array pattern 120. Blind vias, an exemplary one of which is illustrated using reference numeral 114, are used in the FPGA ball grid array pattern 110 and the ASIC ball grid array pattern 120. In accordance with an aspect of the invention, the blind vias 114 on the first surface 102 are coupled to blind vias on the second surface 104 using the through-hole vias 112 as will be described below with respect to FIG. 3.

FIG. 3A is a cross-sectional schematic view illustrating the translator PCB 100 of FIGS. 1, 2A and 2B. Typically, the translator PCB 100 is constructed using a PCB structure 101 having many laminated layers. This structure has been omitted from FIG. 3A for simplicity. However, the detail of the layer structure will be shown in FIG. 3B. Further, while a typical ball grid array pattern for an FPGA and an ASIC will include many hundreds or thousands of contacts, for simplicity only a small number will be illustrated herein.

The first surface 102 (FIG. 2A) of the translator PCB 100 includes the FPGA ball grid array 110 while the second surface 104 (FIG. 2B) of the translator PCB 100 includes the ASIC ball grid array 120. Connectivity from the first surface 102 to the second surface 104 is accomplished using blind vias, exemplary ones of which are illustrated using reference numerals 140 through 145. For example, blind via 140 is formed beginning at the first surface 102, partway through the thickness of the translator PCB 100. Similarly, vias 141 and 142 are formed beginning at the first surface 102, partway through the thickness of the translator PCB 100. Similarly, blind vias 143, 144 and 145 are formed beginning at the second surface 104, partway through the thickness of the translator PCB 100. The inside surfaces of the blind vias are plated so as to be electrically conductive. Solder balls, an exemplary one of which is illustrated using reference numeral 130, are used to provide electrical and mechanical contact between the surface of the blind vias and the contacts on the FPGA 115 and the ASIC (not shown).

It should be noted that the blind vias 140 and 143 are generally vertically aligned but they are mechanically and electrically separated because they do not meet. The blind vias 141 and 144, and the blind vias 142 and 145 are similarly constructed. Furthermore, the blind vias may extend into the PCB structure 101 at different depths.

To connect the blind vias of the FPGA ball grid array pattern 110 to the blind vias of the ASIC ball grid array pattern 120, the blind vias on opposite surfaces of the translator PCB 100 are coupled using connectivity to through-hole vias 150, 152, 153 and 154. For example, the blind via 141 is connected via conductor 161 to through-hole via 152. Similarly, blind via 143 is coupled via conductor 160 to through-hole via 153. In this manner, electrical connection is made between blind via 141 and blind via 143 using through-hole via 152. Similarly, and for exemplary purposes only, blind via 142 is coupled via conductor 162 to through-hole via 154 and blind via 144 is coupled using conductor 163 to through-hole via 154. In this manner, electrical connectivity between blind via 142 and blind via 144 is achieved, while allowing the FPGA ball grid array pattern 110 to reside substantially vertically aligned with respect to the ASIC ball grid array pattern 120.

FIG. 3B is a schematic view illustrating the layer structure of the PCB structure 101. A portion of the detail will be omitted, as it is known to those having ordinary skill in the art. The PCB structure 101 includes a top layer 171, which generally includes a silkscreen layer, a solder paste layer and a solder resist layer. Layer 172 includes a thin first signal layer and a relatively thick layer of prepreg. The prepreg layer is used as an adhesive to bond alternating signal layers.

Layer 174 includes a relatively thick prepreg layer sandwiched between a second signal layer and a ground layer. Layer 176 is another prepreg layer. Layer 178 includes a core layer sandwiched between a third signal layer and a power layer. Layer 179 is another prepreg layer. Layer 181 includes another core layer sandwiched between another signal layer and a power layer. Layer 182 is another prepreg layer.

Layer 184 is another core layer sandwiched between a power layer and another signal layer. Layer 186 is another prepreg layer. Layer 187 is another core layer sandwiched between a power layer and another signal layer. Layer 188 is another prepreg layer. Layer 189 is another core layer sandwiched between a ground layer and another signal layer. Layer 191 includes a relatively thick prepreg layer and another signal layer. Finally, the PCB structure 101 includes a bottom layer 192, which generally includes a solder resist layer, a solder paste layer, and a silkscreen layer. The layers are typically laminated under pressure and raised temperature to form the PCB structure 101.

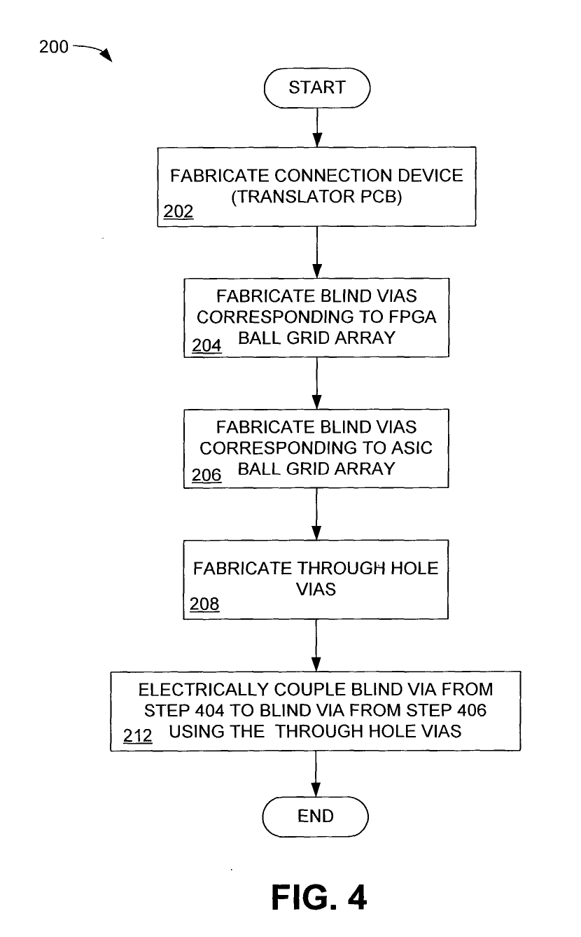

FIG. 4 is a flowchart 200 illustrating the routing methodology described-above with respect to FIG. 3A. In block 202, the PCB 101 structure is fabricated. In block 204, the blind vias 140 through 143 corresponding to the FPGA ball grid array pattern 110 are fabricated. In block 206, the blind vias 143 through 145 corresponding to the ASIC ball grid array pattern 120 are fabricated.

In block 208, the through-hole vias 150, 152, 153 and 154 are fabricated. In block 212, conductors 160, 161, 162 and 163 are routed to couple the blind via 141 to the blind via 143, and to couple the blind via 142 to the blind via 144, using through-hole vias 152 and 154, respectively. In this manner, connectivity is provided from the first surface 102 to the second surface 104 (FIGS. 2A and 2B) while allowing the FPGA ball grid array pattern 110 to reside opposite the ASIC ball grid array pattern 120 on the translator PCB 100.

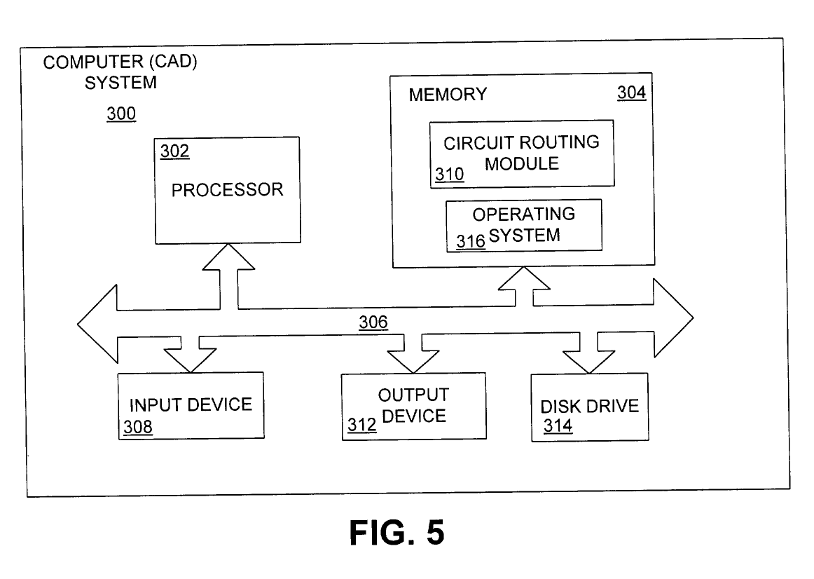

FIG. 5 is a block diagram illustrating a simplified computer system 300 for implementing the circuit routing method described above with respect to FIGS. 3A and 4. The computer system 300 is highly simplified and is intended to show the basic components of a CAD system that may be used to implement the invention. Generally, in terms of hardware architecture, as shown in FIG. 5, the computer system 300 includes a processor 302, memory 304 (one or more random access memory (RAM) elements, read only memory (ROM) elements, etc.), an optional removable media disk drive 314, an input device 308 and an output device 312 that are connected together and can communicate with each other via a local interface 306. The local interface 306 can be, for example but not limited to, one or more buses or other wired or wireless connections, as is known to those having ordinary skill in the art. The local interface 306 may have additional elements, which are omitted for simplicity, such as buffers (caches), drivers, and controllers, to enable communications. Further, the local interface 306 includes address, control, and data connections to enable appropriate communications among the aforementioned components.

The input device 308 can be, for example, a keyboard, mouse, stylus, or any other device for inputting information into the computer system 300. The output device 312 can be a display monitor, a printer, or any other device for presenting information to a user of the computer system 300. Further, the computer system may be coupled to a network (not shown) for sharing files and for communicating with other computer systems coupled to the network. The disk drive 314 can be any storage element or memory device, and as used herein, generally refers to a device having a removable storage media.

The processor 302 is a hardware device for executing software that can be stored in memory 304. The processor 302 can be any suitable processor for implementing the functionality of the computer system 300. The memory 304 can include any one or a combination of volatile memory elements (e.g., random access memory (RAM, such as DRAM, SRAM, etc.)) and nonvolatile memory elements (e.g., RAM, ROM, hard drive, tape, CDROM, etc.). Moreover, the memory 304 may incorporate electronic, magnetic, optical, and/or other types of storage media. Note that the memory 304 can have a distributed architecture, where various components are situated remote from one another, but can be accessed by the processor 302.

The software in memory 304 may include one or more separate programs, each of which comprise one or more code segments, which are an ordered listing of executable instructions for implementing logical functions. In the example of FIG. 5, the software in the memory 304 includes a circuit routing module 310 and one or more operating software modules, collectively referred to as operating system (O/S) 316. The O/S 316 may include software modules that perform some of the functionality of the computer system 300 not specifically described herein.

The operating system 316 essentially controls the execution of other computer programs, such as the circuit routing module 310, and provides scheduling, input-output control, file and data management, memory management, and communication control and related services. The processor 302 and operating system 316 define a computer platform, for which application programs, such as the circuit routing module 310, are written in higher level programming languages. The circuit routing module 310 includes the executable instructions that allow the computer system 300 to perform the circuit routing described above with respect to FIGS. 3A and 4.

When the computer system 300 is in operation, the processor 302 is configured to execute software stored within the memory 304, to communicate data to and from the memory 304 and to generally control operations of the computer system 300 pursuant to the software. The circuit routing module 310 and the O/S 210, in whole or in part, but typically the latter, are read by the processor 302, perhaps buffered within the processor 302, and then executed.

While various embodiments of the invention have been described, it will be apparent to those of ordinary skill in the art that many more embodiments and implementations are possible that are within the scope of this invention. For example, the routing methodology described above can be used to fabricate any printed circuit board and need not be limited to the translator PCB 100 described above. Furthermore, while illustrated above using ball grid array patterns, the invention is applicable to any packaging formats. All such modifications and variations are intended to be included herein within the scope of this disclosure and the present invention and protected by the following claims.

What is claimed is:

1. A system for coupling circuit devices having dissimilar connectivity patterns, comprising:
a connection device having a first connectivity pattern on a first surface and a second connectivity pattern on a second surface;
a first conductor associated with the first connectivity pattern and a second conductor associated with the second connectivity pattern,
a first blind via extending from the first surface partway through the connection device, the first blind via forming the first conductor; and
a second blind via extending from the second surface partway through the connection device, the second blind via forming the second conductor, wherein the first blind via is mechanically isolated from the second blind via and the first blind via is electrically coupled to the second blind via through a common electrical connection to a through-hole via.

2. The system of claim 1, wherein the first and second blind vias are plated holes in the connection device.

3. The system of claim 1, wherein the first connectivity pattern and the second connectivity pattern are substantially vertically aligned and substantially perpendicular to a major axis of the connection device.

4. The system of claim 3, wherein the first connectivity pattern represents the contact locations of a field programmable gate array (FPGA) and the second connectivity pattern represents the contact locations of an application specific integrated circuit (ASIC).

5. The system of claim 1, wherein the connection device is a printed circuit board (PCB).

6. The system of claim 1, wherein the first connectivity pattern and the second connectivity pattern are ball grid arrays.

7. A method for routing conductors on a printed circuit board (PCB), the method comprising:
forming a connection device having a first connectivity pattern on a first surface and a second connectivity pattern on a second surface;
forming a first conductor associated with the first connectivity pattern and a second conductor associated with the second connectivity pattern;
forming a first blind via extending from the first surface partway through the connection device, the first blind via forming the first conductor;
forming a second blind via extending from the second surface partway through the connection device, the second blind via forming the second conductor;
mechanically isolating the first blind via from the second blind via; and
electrically coupling the first blind via to the second blind via through a common electrical connection to a through-hole via.

8. The method of claim 7, wherein the first and second blind vias are plated holes in the connection device.

9. The method of claim 7, wherein the first connectivity pattern and the second connectivity pattern are substantially vertically aligned and substantially perpendicular to a major axis of the connection device.

10. The method of claim 9, wherein the first connectivity pattern represents the contact locations of a field programmable gate array (FPGA) and the second connectivity pattern represents the contact locations of an application specific integrated circuit (ASIC).

11. The method of claim 7, wherein the connection device is a printed circuit board (PCB).

12. The method of claim 7, wherein the first connectivity pattern and the second connectivity pattern are ball grid arrays.

13. A computer-readable medium having a program for routing conductors on a printed circuit board (PCB), the program including logic for performing the steps of:
forming a connection device having a first connectivity pattern on a first surface and a second connectivity pattern on a second surface;
forming a first conductor associated with the first connectivity pattern and a second conductor associated with the second connectivity pattern;
forming a first blind via extending from the first surface partway through the connection device, the first blind via forming the first conductor;
forming a second blind via extending from the second surface partway through the connection device, the second blind via forming the second conductor;
mechanically isolating the first blind via from the second blind via; and
electrically coupling the first blind via to the second blind via through a common electrical connection to a through-hole via.

14. The program of claim 13, wherein the first and second blind vias are plated holes in the connection device.

15. The program of claim 13, wherein the first connectivity pattern and the second connectivity pattern are substantially vertically aligned and substantially perpendicular to a major axis of the connection device.

16. The program of claim 15, wherein the first connectivity pattern represents the contact locations of a field programmable gate array (FPGA) and the second connectivity pattern represents the contact locations of an application specific integrated circuit (ASIC).

17. The program of claim 13, wherein the connection device is a printed circuit board (PCB).

18. The program of claim 13, wherein the first connectivity pattern and the second connectivity pattern are ball grid arrays.
